(19) United States
(12) Patent Application Publication
(10) Pub. No.: US 2025/0070003 A1
(43) Pub. Date: Feb. 27, 2025

(54) WIRING BOARD, SEMICONDUCTOR DEVICE, AND METHOD FOR PRODUCING WIRING BOARD

(71) Applicant: TOPPAN Holdings Inc., Tokyo (JP)

(72) Inventor: Kenta SUGAWARA, Tokyo (JP)

(73) Assignee: TOPPAN Holdings Inc., Tokyo (JP)

(21) Appl. No.: 18/923,761

(22) Filed: Oct. 23, 2024

Related U.S. Application Data
(63) Continuation of application No. PCT/JP2023/016877, filed on Apr. 28, 2023.

(30) Foreign Application Priority Data
Apr. 28, 2022 (JP) 2022-075341

(51) Int. Cl. H01L 23/498; H01L 23/00; H05K 1/11; H05K 3/18

(52) U.S. Cl. CPC H01L 23/49816; H01L 23/49838; H01L 23/49866; H01L 24/06; H01L 24/13; H05K 1/113; H05K 3/188; H01L 24/05; H01L 2224/05009; H01L 2224/0603; H01L 2224/13007; H01L 2224/13023; H01L 2924/1511; H01L 2924/15321

(57) ABSTRACT

The present invention is a wiring board with a multi-layer structure having a plurality of build-up layers, wherein, among the build-up layers, a build-up layer on a front surface side formed last has a first solder pad and a second solder pad, a solder resist layer is provided on the front surface side of the build-up layer on a front surface side, and heights of the first solder pad and the second solder pad from front surfaces thereof to a front surface of the solder resist layer are different from each other.

### CROSS-REFERENCE TO RELATED APPLICATIONS

The present application is a continuation application of International Application No. PCT/JP2023/016877, filed Apr. 28, 2023, which claims priority to Japanese Patent Application No. 2022-075341, filed Apr. 28, 2022. The content of these applications are incorporated herein by reference in their entirety.

### FIELD

The present invention relates to a wiring board, a semiconductor device, and a method for producing a wiring board.

### BACKGROUND

In the related art, as a semiconductor device on which semiconductor elements (semiconductor chips) are mounted, a semiconductor device of a wire bonding connection type that uses a thin metal wire such as a gold wire is known. In addition, in order to meet recent demands for a semiconductor device to be smaller, thinner, faster, and more highly integrated, a semiconductor device in which semiconductor chips are mounted on a flip-chip bonding type wiring board (an FC-BGA wiring board) that is formed to be bondable to electrodes of semiconductor chips via conductive protrusions called solder balls is widely known (see, for example, Japanese Unexamined Patent Application, First Publication No. 2001-85558).

In addition, in the field of a server, a high-end computer (HPC), or the like, a processor is constituted by a plurality of multi-CPUs or a so-called multi-core, which increases the processing speed and significantly increases the amount of information that the processor handles. Accordingly, the transmission capacity between the processor and the outside is increased dramatically, and there is also a demand for a higher transmission speed. Along with this increase in transmission capacity and the demand for high-speed transmission, progress is being made in the development of optical interconnection technology that uses optical signals for information processing within a router or a server. It is also desirable for a device, a semiconductor package, or the like that uses the optical interconnection technology to be compatible with the mounting type for electrical interconnection of the related art. In recent years, as a mounting type for optical interconnection, various types of optical/electrical hybrid boards in which optical semiconductor elements (semiconductor chips) that transmit and receive optical signals are mounted on an FC-BGA wiring board have been proposed (see, for example, Japanese Unexamined Patent Application, First Publication No. 2011-107206).

Incidentally, in a case in which a plurality of semiconductor chips having different thicknesses (heights) are mounted on a wiring board, it is desirable that the heights of upper surfaces of the semiconductor chips be aligned for convenience in design of the wiring board or the semiconductor chips, ease in attachment of a heat spreader to be mounted on the upper portions of the semiconductor chips, and the like. However, the optical semiconductor elements (the semiconductor chips) mounted on the optical/electrical hybrid board described in Japanese Unexamined Patent Application, First Publication No. 2011-107206 are often thicker (higher) than semiconductor chips that handle only electrical signals. For this reason, in a printed wiring board on which semiconductor chips having different thicknesses (heights) are directly mounted, the heights of the upper surfaces of the semiconductor chips will differ from each other.

In order to align the heights of the upper surfaces of the plurality of semiconductor chips that have been mounted, as disclosed in Japanese Unexamined Patent Application, First Publication No. 2001-85558, a semiconductor device in which the heights from electrodes of the board to electrodes of the semiconductor chips can be individually adjusted by changing the sizes of the solder balls has been devised. However, in the semiconductor device of Japanese Unexamined Patent Application, First Publication No. 2001-85558, a pitch between the solder balls has to be changed in accordance with the difference in size between the solder balls. If larger or smaller solder balls than usual solder balls are mounted without changing the pitch between the solder balls, there is a problem that the solder balls are bonded together during reflow, resulting in unnecessary bonding, or the solder balls do not reach the electrodes of the semiconductor chips and therefore cannot be bonded thereto.

In addition, the solder balls can be mounted on any of semiconductor chips, semiconductor packages, and a printed wiring board. In a case in which the solder balls are mounted on a printed wiring board, solder balls having different diameters cannot be mounted at the same time. For this reason, there is a problem that the number of processes increases because the mounting of the solder balls is repeated multiple times for each diameter of the solder balls, and furthermore, in mounting the solder balls having different diameters separately for each diameter, the time and effort required to consider the order of the mounting increase.

### SUMMARY

The present invention has been made in consideration of the above circumstances, and an object of the present invention is to provide a wiring board, a semiconductor device, and a method for producing a wiring board in which the heights of upper surfaces of mounted products can be aligned even in a case in which semiconductor packages or semiconductor chips having different heights are mounted while making a pitch interval between solder balls uniform.

In order to solve the above problems, the present invention proposes the following means.

A first aspect of the present invention is a wiring board with a multi-layer structure having a plurality of build-up layers, wherein, among the build-up layers, a build-up layer on a front surface side formed last has a first solder pad and a second solder pad, a solder resist layer is provided on the front surface side of the build-up layer on a front surface side, and heights of the first solder pad and the second solder pad from front surfaces thereof to a front surface of the solder resist layer are different from each other.

A second aspect of the present invention is the wiring board according to the first aspect, wherein the solder resist layer includes opening portions through which the front surface of the first solder pad and the front surface of the second solder pad are exposed to the front surface side, and the front surface of the solder resist layer excluding the opening portions has an approximately uniform height.

A third aspect of the present invention is the wiring board according to the first aspect or the second aspect, wherein the build-up layer on the front surface side further includes a third solder pad, and the first solder pad, the second solder pad, and the third solder pad are formed at equal intervals.

A fourth aspect of the present invention is the wiring board according to the first aspect or the second aspect, wherein the first solder pad and the second solder pad include solder balls having approximately a same diameter and approximately a same shape on the front surface side.

A fifth aspect of the present invention is the wiring board according to the fourth aspect, wherein the first solder pad and the second solder pad are formed such that a difference between the heights is determined by heights of semiconductor chips to be bonded to the front surface side of the solder balls.

A sixth aspect of the present invention is the wiring board according to the fourth aspect, wherein the first solder pad and the second solder pad are formed such that a difference between the heights is determined by heights of mounting pad portions of the semiconductor chips to be bonded to the front surface side of the solder balls.

A seventh aspect of the present invention is a semiconductor device including: the wiring board according to the fifth aspect; and the semiconductor chips

An eighth aspect of the present invention is a semiconductor device including: the wiring board according to the sixth aspect; the semiconductor chips; and the mounting pad portion.

A ninth aspect of the present invention is a method for producing a wiring board, wherein, among a plurality of build-up layers, a build-up layer on a front surface side formed last has a first solder pad and a second solder pad, a solder resist layer is provided on the front surface side of the build-up layer on a front surface side, and heights of the first solder pad and the second solder pad from front surfaces thereof to a front surface of the solder resist layer are different from each other. The method comprises at least: a step of forming a wiring layer, the first solder pad, and the second solder pad in the build-up layer on a front surface side; a step of forming a plating resist layer such that a part of the front surface of the first solder pad and a part of the front surface of the second solder pad are exposed to the front surface side; a step of depositing copper on the front surface side of the first solder pad and the second solder pad by a copper plating treatment; a step of stripping the plating resist layer; a step of forming the solder resist layer on the front surface side of the build-up layer on the front surface side; and a step of providing, in the solder resist layer, opening portions through which a part of the front surface of the first solder pad and a part of the front surface of the second solder pad are exposed to the front surface side.

According to the wiring board, the semiconductor device, and the method for producing a wiring board of the present invention, the heights of upper surfaces of mounted products can be aligned even in a case in which semiconductor packages or semiconductor chips having different heights are mounted while making a pitch interval between solder balls uniform. In addition, the solder resist layer covers the solder pads, which have different solder heights, at a uniform height. For this reason, when an underfill is injected between the wiring board and the semiconductor chips after the semiconductor chips are mounted, the flow of the underfill is not hindered by steps and spreads smoothly, resulting in a significant improvement in the productivity of an underfilling process.

### BRIEF DESCRIPTION OF THE DRAWINGS

FIG. 1 is a diagram showing a cross section of an FC-BGA wiring board according to a first embodiment of the present invention.

FIG. 2 is a diagram showing an example of a step of producing a wiring board for the same FC-BGA wiring board.

FIG. 3 is a diagram showing an example of a step of producing a wiring board for the same FC-BGA wiring board.

FIG. 4 is a cross-sectional view showing an example of a semiconductor device in which semiconductor chips are mounted on an FC-BGA wiring board according to a second embodiment of the present invention.

FIG. 5 is a cross-sectional view showing an example of a semiconductor device in which semiconductor chips are mounted on an FC-BGA wiring board according to a third embodiment of the present invention.

FIG. 6 is a diagram showing a modification example of a semiconductor device in which a semiconductor chip and a heat spreader are mounted on the FC-BGA wiring board according to the third embodiment of the present invention.

### DETAILED DESCRIPTION

### First Embodiment

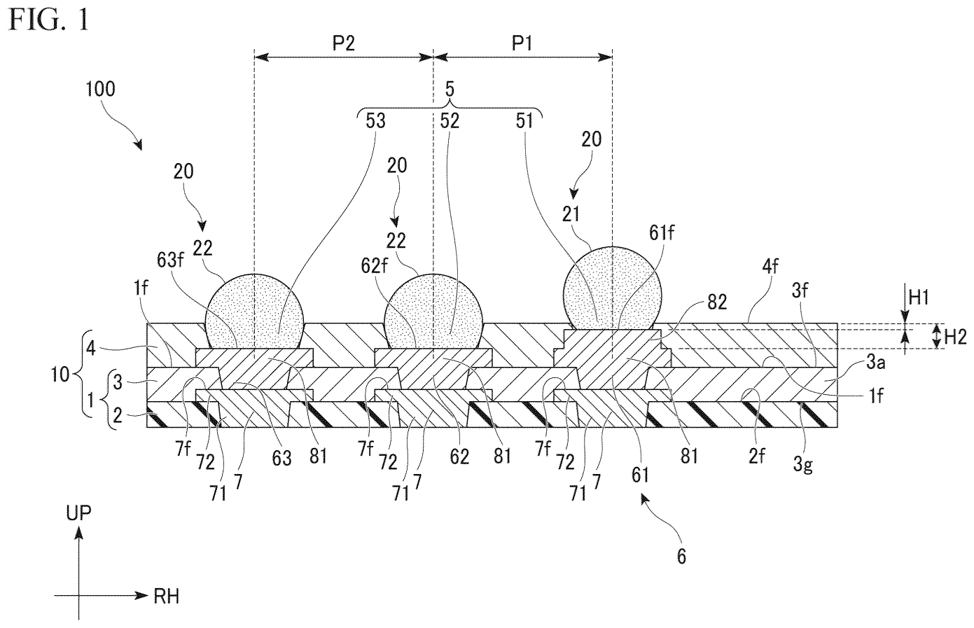

A first embodiment of the present invention will be described with reference to FIGS. 1 to 3. In the embodiments and modification example, which will be described below, constituent elements corresponding to each other are designated by the same reference signs, and descriptions of duplicate parts may be omitted. In addition, in the following description, expressions indicating relative or absolute arrangements, such as “parallel,” “orthogonal,” “central,” and “coaxial,” are intended to not only indicate such arrangements strictly, but also to indicate a state in which there is a relative displacement with a tolerance or an angle or distance to the extent that the same function is obtained.

Here, as shown in FIG. 1, UP indicates an upward side and RH indicates a right side. In addition, in the following description of an FC-BGA wiring board 100, a vertical direction is defined as an upward-downward direction (arrow UP indicates an upward side). In addition, a surface provided on an upward side in the upward-downward direction is defined as an upper surface (a front surface), and a surface provided on a downward side opposite to the upward side is defined as a lower surface (a back surface). Furthermore, a horizontal direction orthogonal to the upward-downward direction is defined as a left-right direction (arrow RH indicates a right side). In the left-right direction, a direction opposite to the right side is defined as a left side. As shown in FIG. 1, an FC-BGA wiring board 100 (a wiring board) according to the first embodiment of the present invention includes a wiring board 10 and solder balls 20.

The wiring board 10 is a board with a multi-layer structure having a plurality of build-up layers. The wiring board 10 includes build-up layers (wiring layers) 1 and a solder resist layer 4.

The build-up layers (the wiring layers) 1 are layers obtained by stacking a plurality of wiring layers. The build-up layers 1 include a first layer 2 and a second layer 3. The build-up layers 1 are not limited to the multi-layer structure in which two layers are stacked as shown in FIG. 1, and may be a multi-layer structure in which three or more layers are stacked.

As shown in FIG. 1, the first layer 2 is one layer of the build-up layers 1 and is formed on the downward side. The first layer 2 is formed by layering interlayer insulating materials made of an epoxy resin or the like and laminating them using a hot-pressing machine or the like. The interlayer insulating material may be, for example, a thermosetting resin. Further, in some cases, as the interlayer insulating material, a material in which glass cloth is contained is used. The first layer 2 may be formed of paper, other resins, or the like. The first layer 2 includes a plurality of third conductor portions 7 in a part thereof.

Each of the third conductor portions 7 is formed of a conductive material containing a metal such as copper as a main component. A part of the first layer 2 shown in FIG. 1 includes three third conductor portions 7 having approximately the same shape and approximately the same size. The third conductor portions 7 are provided in a part of the first layer 2 to be aligned in a row in the left-right direction.

Each of the third conductor portions 7 shown in FIG. 1 has a pad-on-via structure in which an interlayer conductive portion 71 called a via is provided on a pad portion 72. However, the third conductor portion 7 is not limited to a conductor portion having the pad-on-via structure. The third conductor portion 7 may include the pad portion 72 at a position that does not overlap the interlayer conductive portion 71 in the upward-downward direction using a wiring or the like that connects the pad portion 72 and the interlayer conductive portion 71 to each other.

The interlayer conductive portion 71 is formed in a hole passing through the first layer 2 together with the pad portion 72 by electrolytic copper plating or the like. An upper surface of the interlayer conductive portion 71 is at approximately the same height as an upper surface 2f of the first layer 2.

The pad portion 72 is provided above the interlayer conductive portion 71. The pad portion 72 is formed together with the interlayer conductive portion 71 by electrolytic copper plating or the like. The pad portion 72 protrudes upward from the first layer 2, and the upper surface of the pad portion 72 is an upper surface 7f of the third conductor portion 7.

The third conductor portion 7 is formed by integrating the interlayer conductive portion 71 and the pad portion 72 with each other by a plating treatment using a semi-additive method, which will be described below. Moreover, the upper surfaces 7f of the three third conductor portions 7 have approximately the same height in the upward-downward direction.

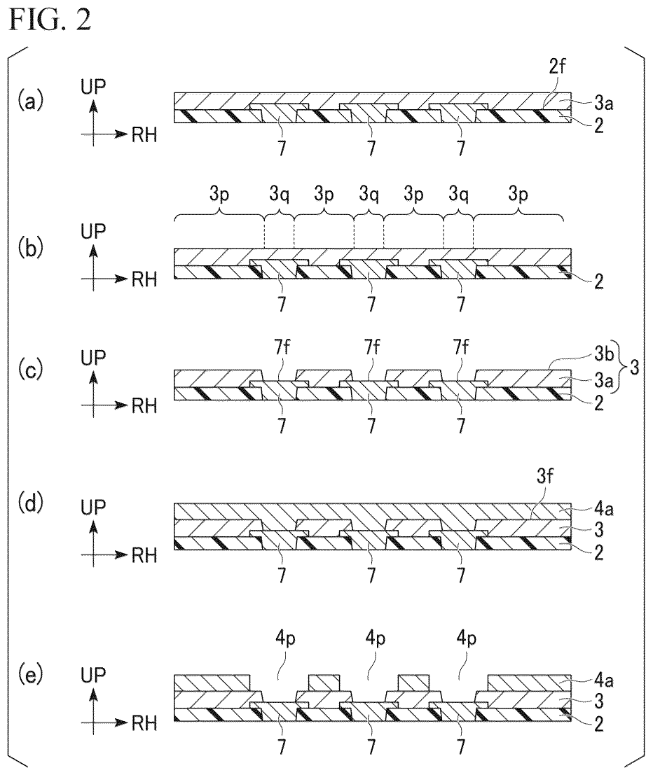

The second layer 3 is stacked on the upper surface (the front surface) 2f provided on the upward side of the first layer 2. The second layer 3 is a layer of the build-up layers 1 which is formed last on an upper surface 1f of the build-up layer 1. The second layer 3 is formed, for example, by layering film-like interlayer insulating materials and laminating them using a hot-pressing machine or the like, similar to the first layer 2. As the film-like interlayer insulating material, a thermosetting resin that hardens due to the heat applied during the laminating can be used. Furthermore, in a case in which a hole for a via is opened on a laminated interlayer insulating material by a photolithography method, the second layer 3 can be made of a photosensitive insulating resin as the interlayer insulating material. In the present embodiment, as the second layer 3, a photosensitive insulating resin layer 3a (see a part (a) of FIG. 2 and the like), which will be described below, is used.

A part of the second layer 3 shown in FIG. 1 has a plurality of solder pads 6. As shown in FIG. 1, three solder pads 6 are provided in a part of the second layer 3 to be aligned in a row in the left-right direction. The plurality of solder pads 6 are arranged, for example, in a lattice pattern on a side of the upper surface 2f of the first layer 2. Each of the solder pads 6 shown in FIG. 1 is stacked above the third conductor portion 7 to form a stacked via. However, the solder pad 6 does not have to be formed in a stacked manner like a stacked via, and may be formed, for example, in a stepped shape like a staggered via or in other shapes.

In the present embodiment, the solder pad 6 has a pad-on-via structure in which the solder pad 6 is constituted by a pad and a via provided in the pad, similar to the third conductor portion 7. However, the solder pad 6 is not limited to the pad-on-via structure, and the pad may be provided at a position that does not overlap the via in the upward-downward direction by using a wiring or the like. Furthermore, the solder pad 6 may be formed using a land, a wiring, and the like.

The solder pad 6 is formed by a plating treatment which will be described below. The solder pad 6 serve as an electrode for bonding to a semiconductor element. The solder pad 6 includes a first solder pad 61, a second solder pad 62, and a third solder pad 63. In the present embodiment, the second solder pad 62 and the third solder pad 63 have approximately the same shape and size as shown in FIG. 1, and thus a description of the third solder pad 63 will be omitted. Here, a pitch interval from the center of the first solder pad 61 to the center of the second solder pad 62 in the left-right direction is defined as a pitch P1. In addition, a pitch interval from the center of the second solder pad 62 to the center of the third solder pad 63 is defined as a pitch P2. In the present embodiment, the lengths of the pitch P1 and the pitch P2 are approximately the same. For this reason, the first solder pad 61, the second solder pad 62, and the third solder pad 63 are formed in the second layer 3 at equal intervals. The lengths of the pitch P1 and the pitch P2 do not have to be the same.

The first solder pad 61 is provided above the third conductor portion 7 on the most right side of the three third conductor portions 7. Since the solder pad 6 is not limited to a stacked via, the first solder pad 61 does not have to be provided above the third conductor portion 7. The first solder pad 61 is provided to the right of the second solder pad 62 and the third solder pad 63. As shown in FIG. 1, the first solder pad 61 includes a first conductor portion 81 and a second conductor portion 82.

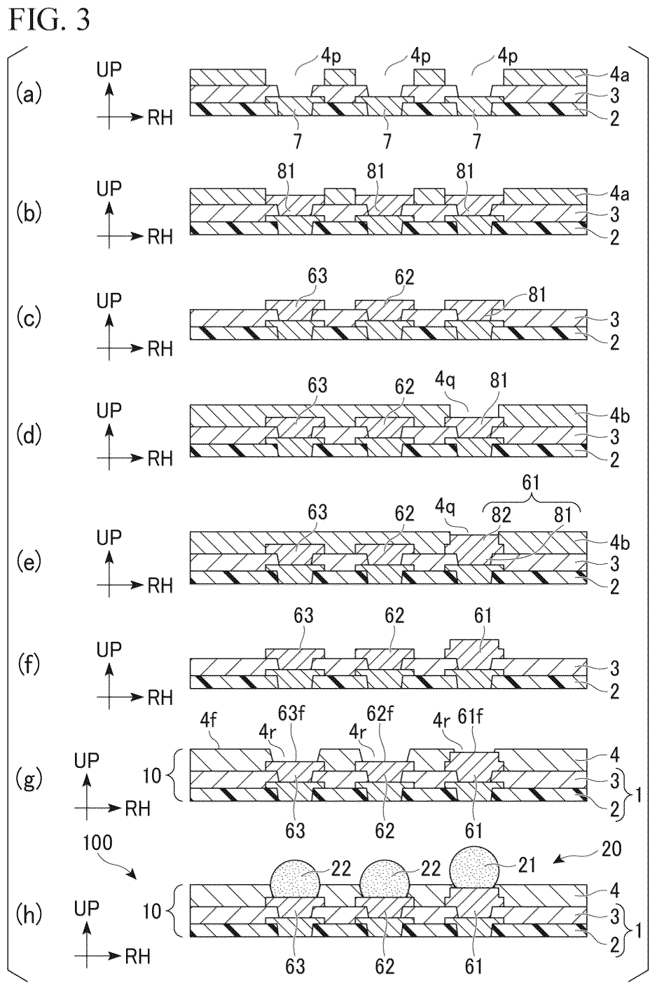

The first conductor portion 81 is a plated portion provided above the pad portion 72 of the third conductor portion 7. The first conductor portion 81 is formed by a plating treatment using a semi-additive method, which will be described below. The first conductor portion 81 is constituted by, for example, an upper pad and a lower via formed in a through hole passing through the second layer 3. The first conductor portion 81 is formed, for example, by performing a plating treatment on each opening portion (a first resist opening 4p, see a part (a) of FIG. 3) opened by exposure and development, which will be described below. In addition, as shown in a part (b) of FIG. 3, the first conductor portions 81 formed in the opening portions are formed such that the upper surfaces of the first conductors 81 are at the same height in the upward-downward direction. The first conductor portion 81 is formed with an upper pad larger than the inner diameter of the opening portion, and protrudes upward from the second layer 3. The first conductor portion 81 may further include a land, a wiring, and the like.

The second conductor portion 82 is a plated layer provided above the first conductor portion 81. The second conductor portion 82 is formed by a plating treatment using a semi-additive method, which will be described below. The outer diameter of the second conductor portion 82 is smaller than the outer diameter of the upper pad of the first conductor portion 81. After the first conductor portion 81 is formed by a plating treatment which will be described below, the second conductor portion 82 is formed above the first conductor portion 81 by a further plating treatment. The first conductor portion 81 and the second conductor portion 82 are integrated with each other to form the first solder pad 61

The second solder pad 62 includes the first conductor portion 81 described above. The second solder pad 62 does not include the second conductor portion 82. The second solder pad 62 is formed between the first solder pad 61 and the third solder pad 63.

The second solder pad 62 and the third solder pad 63 each having the first conductor portion 81 are formed such that the heights of the upper surfaces 62f and 63f of the second solder pad 62 and the third solder pad 63 in the upward-downward direction are approximately the same, as shown in a part (c) of FIG. 3. In addition, the height of the upper surface 61f of the first solder pad 61 having the first conductor portion 81 and the second conductor portion 82 is higher than that of each of the upper surfaces 62f and 63f of the second solder pad 62 and the third solder pad 63 by the height of the second conductor portion 82.

The solder resist layer 4 is a layer stacked on the upper surface (the front surface) 1f of the build-up layers 1. An upper surface 4f of the solder resist layer 4 is the upper surface of the wiring board 10. The solder resist layer 4 may be made of a photosensitive insulating resin containing, for example, a phenolic resin or a polyimide resin as a main component, and may contain a filler such as silica or alumina. The solder resist layer 4 includes an opening portion 5

The opening portion 5 is a hole formed in the solder resist layer 4. The opening portion 5 includes a first opening portion 51, a second opening portion 52, and a third opening portion 53. As shown in FIG. 1, the second opening portion 52 and the third opening portion 53 have approximately the same shape and size, and therefore a description of the third opening 53 will be omitted.

The first opening portion 51 is formed in the upper surface 4f of the solder resist layer 4, and a part of each of the solder balls 20, which will be described below, is accommodated in the first opening portion 51. The first opening portion 51 is formed above the first solder pad 61 and on a right side of the second opening portion 52 and the third opening portion 53. The bottom surface of the first opening portion 51 is approximately aligned with the upper surface 61f of the first solder pad 61 among the solder pads 6 of the second layer 3. The size of the inner diameter of the first opening portion 51 is smaller than the upper surface 61f of the first solder pad 61.

The second opening portion 52 is formed in the upper surface 4f of the solder resist layer 4, and a part of each of the solder balls 20, which will be described below, is accommodated in the second opening portion 52. The second opening portion 52 is formed above the second solder pad 62. The bottom surface of the second opening portion 52 is approximately aligned with the upper surface 62f of the second solder pad 62 among the solder pads 6 of the second layer 3. In addition, the size of the inner diameter of the second opening portion 52 is smaller than the upper surface 62f of the second solder pad 62. In addition, the third opening portion 53 is formed above the third solder pad 63.

The first opening portion 51, the second opening portion 52, and the third opening portion 53 formed above the three solder pads 6 are arranged in this order from the right side in the left-right direction. That is, the first opening portion 51, the second opening portion 52, and the third opening portion 53 are provided above the solder pads 6, and are formed at equal intervals in the solder resist layer 4.

In the upward-downward direction, the height of the upper surface 4f of the solder resist layer 4 is uniform. As described above, the height of the upper surface 61f of the first solder pad 61 is higher than that of each of the upper surfaces 62f and 63f of the second solder pad 62 and the third solder pad 63 by the height of the second conductor portion 82. Here, as shown in FIG. 1, a height from the upper surface 61f of the first solder pad 61 to the upper surface 4f of the solder resist layer 4 is defined as H1. A height from each of the height of the upper surface 62f of the second solder pad 62 and the height of the upper surface 63f of the third solder pad 63 to the upper surface 4f of the solder resist layer 4 is defined as H2. The height H1 is smaller than the height H2 by the height of the second conductor portion 82. For this reason, the height H1 and the height H2 are different from each other.

Each of the solder ball 20 is formed, for example, containing tin (Sn) as a main component, and is, for example, a tin-silver based solder (a SnAg based solder). The solder balls 20 include a first solder ball 21 and a second solder ball 22. The solder ball 20 may be formed of the same material as the solder pad 6

The first solder ball 21 is formed on the upper surface 61f of the first solder pad 61 in a dome shape with an upper portion thereof to be upwardly convex. A part of a lower portion of the first solder ball 21 is accommodated in the first opening portion 51

The second solder ball 22 is formed on each of the upper surface 62f of the second solder pad 62 and the upper surface 63f of the third solder pad 63 in a dome shape with an upper portion thereof to be upwardly convex. A part of the lower portion of the second solder ball 22 is accommodated in each of the second opening portion 52 and the third opening portion 53. In the present embodiment, the first solder ball 21 and the second solder ball 22 are formed to have approximately the same shape and size

Next, an example of producing steps for the above-mentioned FC-BGA wiring board 100 will be described with reference to FIGS. 2 and 3.

In the present embodiment, the wiring board 10 of the FC-BGA wiring board 100 is produced using a semi-additive method. In the wiring board 10, for example, a reverse pattern of a wiring pattern to be formed on the upper surface of a seed layer such as a seed layer 3b (see a part (c) of FIG. 2), which will be described below, is formed using a resist pattern. Thereafter, the wiring board 10 is subjected to electrolytic copper plating to form the third conductor portions 7 in the first layer 2, the first conductor portions 81 in the second layer 3, and the second conductor portion 82. Next, the resist pattern is removed, and finally, the seed layer is removed by a flash etching treatment to form the wiring board 10

First, as shown in the part (a) of FIG. 2, a negative photosensitive insulating resin is applied or laminated onto the upper surface 2f of the first layer 2 to form the insulating resin layer 3a. Here, the third conductor portions 7 are formed in the first layer 2 by a method well-known in the related art.

Next, as shown in a part (b) of FIG. 2, portions at which the insulating resin layer 3a is entirely left are designated as exposed portions 3p, and portions above the positions at which the third conductor portions 7 are formed are designated as unexposed portions 3q, and then exposure is performed, followed by development. The exposure illuminance of the exposed portions 3p in this exposure step is preferably less than 20,000 W/cm², and more preferably 10,000 W/cm² or less.

As shown in the part (c) of FIG. 2, through holes passing through the insulating resin layer 3a are formed below the unexposed portions 3q by development. If necessary, a plasma treatment is performed on the through holes to remove the resin residue

Thereafter, as shown in the part (c) of FIG. 2(c), a seed layer 3b is formed on the upper surface of the insulating resin layer 3a by using a sputtering method or vacuum vapor deposition method as a metal thin film, a chemical copper plating film, or the like. The seed layer 3b is a thin film layer that provides electrical conductivity. The seed layer 3b is removed by a flash etching treatment in a semi-additive method. Through the above producing steps, the second layer 3 is formed.

Next, as shown in a part (d) of FIG. 2, a first resist layer (a plating resist layer) 4a is formed on an upper surface 3f of the second layer 3 by coating or laminating.

Thereafter, as shown in a part (e) of FIG. 2 and a part (a) of FIG. 3, first resist openings 4p are formed above the through holes in the second layer 3 by exposure and development.

Thereafter, as shown in parts (b) and (c) of FIG. 3, a plating (depositing) treatment is performed by electrolytic copper plating until the opening portions (the first resist opening portions 4p) are filled, and first, the first conductor portions 81 are formed in the opening portions. The heights of the first conductor portions 81 at the opening portions are set such that the upper surfaces of the first conductors 81 are at the same height in the upward-downward direction. The material for the first conductor portions 81 may be, for example, a metal such as Cu or Ni, or an alloy containing at least one metal selected from these metals. Through the above steps, the two first conductor portions 81 formed on the left side become the second solder pad 62 and the third solder pad 63, respectively.

Thereafter, as shown in the part (c) of FIG. 3, the first resist layer (the plating resist layer) 4a is stripped using a stripping solution dedicated to the plating resist to be used or a stripping solution having functions equivalent to the dedicated stripping solution.

Next, as shown in a part (d) of FIG. 3, a second resist layer (a plating resist layer) 4b is formed on the upper surfaces of the second layer 3 and the first conductor portions 81 by coating or laminating. Thereafter, a second resist opening portion 4q is formed on the first conductor portion 81 formed on the most right side by exposure and development.

Thereafter, as shown in a part (e) of FIG. 3, a plating (depositing) treatment is performed by electrolytic copper plating until the second resist opening portion 4q is filled, and the second conductor portion 82 is formed. The material for the second conductor portion 82 may be, for example, a metal such as Cu or Ni, or an alloy containing at least one metal selected from these metals, similar to the first conductor portion 81.

Through the above steps, the first conductor portion 81 and the second conductor portion 82 are integrated with each other to form the first solder pad 61. In the present embodiment, the first conductor portion 81 and the second conductor portion 82 are formed of the same type of metal

Thereafter, as shown in a part (f) of FIG. 3, the second resist layer (the plating resist layer) 4b is stripped using a stripping solution dedicated to the plating resist to be used or a stripping solution having functions equivalent to the dedicated stripping solution

In addition, if necessary, an electrolytic copper-plated portion that has been excessively deposited is removed by physical or chemical polishing.

Here, the first resist layer 4a and the second resist layer 4b are used to form the opening portions for electrolytic plating before the electrolytic plating is performed on the seed layer 3b. In the case of a non-photosensitive plating resist layer, a method of forming the opening portions by screen printing, or a method of removing a desired portion by irradiating it with a laser beam to form the opening portions may be used. In the case of a photosensitive plating resist layer, the opening portions are formed through exposure and development steps. There is no particular need to limit the material of the plating resist layer as long as it is a material that can withstand an electrolytic plating bath. For example, in a case in which the electrolytic plating bath is a copper sulfate plating bath, which is acidic, any acid-resistant material may be used, and ordinary dry film resists or various liquid resists may be used.

Furthermore, the first conductor portion 81 and the second conductor portion 82 may be a plated layer that is harder and less likely to be polished than the copper-plated portion, in addition to the copper-plated portion. For example, nickel plating can be suitably used.

Next, as shown in a part (g) of FIG. 3, the solder resist layer 4 is formed on the upper surfaces of the second layer 3, the first solder pad 61, the second solder pad 62, and the third solder pad 63 by coating or laminating. Thereafter, opening portions 4r having a radius of approximately the same size as the first solder ball 21 and the second solder ball 22 are formed on the upper surface 61f of the first solder pad 61, the upper surface 62f of the second solder pad 62, and the upper surface 63f of the third solder pad 63 by exposure and development. Here, the formed opening portions 4r are the first opening portion 51, the second opening portion 52, and the third opening portion 53 described above. In this state, a part of the upper surface 61f of the first solder pad 61, a part of the upper surface 62f of the second solder pad 62, and a part of the upper surface 63f of the third solder pad 63 are each exposed upward. The bottom portion of the opening portion 4r of the solder resist layer 4 may be subjected to a surface treatment as required. In addition, the height of the upper surface 4f of the solder resist layer 4 excluding the opening portion 4r is uniform.

Thereafter, as shown in a part (h) of FIG. 3, solder paste or flux is screen-printed on the first solder pad 61, the second solder pad 62, and the third solder pad 63 of the build-up layers 1 of the wiring board 10, and then ball-shaped electrode terminals (the solder balls) are inserted and reflowed to form the solder balls 20, completing the FC-BGA wiring board 100. Through the above producing steps, the FC-BGA wiring board 100 is formed. The steps of the part (a) of FIG. 2 to the part (h) of FIG. 3 can be repeatedly performed to form any number of layers on the upper surface of the wiring board 10.

In the present embodiment, the above producing method makes it possible to produce the FC-BGA wiring board 100 that has the solder pads 6 with different heights in some parts. For this reason, in the above producing method, by adjusting the height H1 and the height H2, the upper surface height of the first solder ball 21 and the upper surface height of the second solder ball 22, which has approximately the same size and shape as the first solder ball 21, can be adjusted arbitrarily

In addition, in the present embodiment, the height H1 and the height H2 can be adjusted arbitrarily. That is, in the method for producing the FC-BGA wiring board 100, the upper surface 4f of the solder resist layer 4 can be set to a uniform height while adjusting the height of each of the solder pads 6. For this reason, for example, when a liquid resin for sealing an integrated circuit, such as an underfill, is mounted on the FC-BGA wiring board 100 having the upper surface 4f as the upper surface, good mounting properties can be maintained without impeding the flow of the liquid resin.

In addition, in the present embodiment, the pitch P1 and the pitch P2 are formed to have approximately the same length. For this reason, for example, in a case in which a semiconductor chip or the like is mounted on the solder balls 20, it is possible to use the semiconductor chip without matching the length between electrodes (mounting pad portions) on a side of the semiconductor chip to the solder balls 20 of the FC-BGA wiring board 100. Furthermore, since the pitch P1 and the pitch P2 have approximately the same length, the producing of the semiconductor chip becomes easier, and the time and effort required for the producing steps can be reduced.

### Second Embodiment

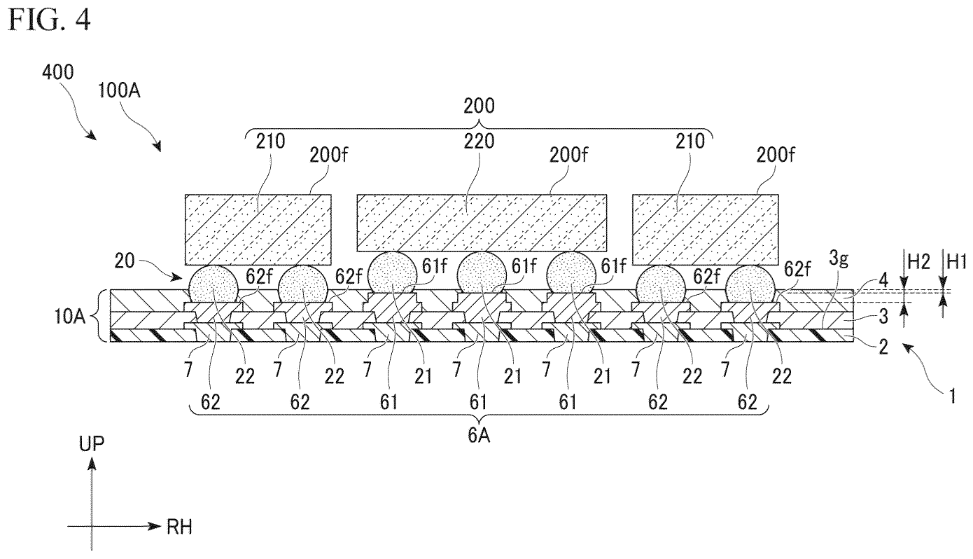

Next, a second embodiment of the present invention will be described with reference to FIG. 4. In the following description, the same constituent elements as those already described are designated by the same reference signs, and duplicate description will be omitted. In any of the following embodiments, the wiring board is different from that of the first embodiment. Therefore, the following description will focus on the differences from the first embodiment. A semiconductor device 400 according to the second embodiment of the present invention includes semiconductor chips 200 in addition to an FC-BGA wiring board 100A. As shown in FIG. 4, the semiconductor chips 200 include a semiconductor chip for optical communication 210 and a semiconductor chip for electrical communication 220. The semiconductor chip for electrical communication 220 is lower in height than the semiconductor chip for optical communication 210 in the upward-downward direction. The FC-BGA wiring board 100A includes a wiring board 10A and solder balls 20. The semiconductor chips 200 may also include mounting pad portions (not shown). The mounting pad portions are provided below the semiconductor chips 200 and are bonded to the solder balls 20 to electrically connect the semiconductor chips 200 and the wiring board 10A to each other.

The wiring board 10A includes solder pads 6A on a part of a second layer 3 shown in FIG. 4. As shown in FIG. 4, in the wiring board 10A, the number of the solder pads 6A is different from that in the first embodiment. The solder pads 6A include, from the right side, two second solder pads 62, three first solder pads 61, and two second solder pads 62, which are aligned in a row in the left-right direction. The solder pads 6A are provided at approximately equal intervals.

The difference in height between the height H1 and the height H2 in the upward-downward direction is adjusted arbitrarily such that in a case in which the semiconductor chips 200 are bonded (mounted) to the solder balls 20 from above, upper surfaces 200f of the semiconductor chips 200 are all at approximately the same height from a lower surface 3g of the second layer 3 having the solder pads 6A. That is, the height difference between the height H1 and the height H2 is determined by the heights of the semiconductor chips 200. In the present embodiment, similar to the first embodiment, the height H1 is smaller than the height H2. In addition, in a case in which the semiconductor chips 200 have the mounting pad portions, the difference between the height H1 and the height H2 may be determined by the heights of the mounting pad portions.

The solder balls 20 include first solder balls 21 and second solder balls 22, similar to the first embodiment. The first solder balls 21 are formed on the upper surfaces 61f of the first solder pads 61. The second solder balls 22 are formed on the upper surfaces 62f of the second solder pads 62. The first solder balls 21 and the second solder balls 22 are formed to have approximately the same size and shape.

Next, the semiconductor chips 200 are mounted on the FC-BGA wiring board 100A.

As shown in FIG. 4, first, the electrodes (the mounting pad portions) of the two semiconductor chips for optical communication 210 are mounted to abut against the second solder balls 22 formed on the upper surfaces 62f of the second solder pads 62 of the wiring board.

Next, the electrodes (the mounting pad portions) of the semiconductor chip 220 for electrical communication, which is lower in height in the upward-downward direction than the semiconductor chip for optical communication 210, are mounted to abut against the first solder balls 21 formed on the upper surface 61f of the first solder pad 61 of the wiring board 10A. At this time, since the height H1 is set smaller than the height H2, even if the semiconductor chip for electrical communication 220 is lower than the semiconductor chip for optical communication 210, the upper surfaces 200f of all the semiconductor chips 200 are at approximately the same height.

With the above configuration, a plurality of semiconductor chips 200 are mounted on the FC-BGA wiring board 100A, and the semiconductor device 400 is formed

In the present embodiment, the height H1 and the height H2 can be adjusted in accordance with the heights of the plurality of semiconductor chips 200. For this reason, after the plurality of semiconductor chips 200 are mounted, the upper surfaces 200f of all the semiconductor chips 200 can be set to be at approximately the same height. Furthermore, when, for example, a heat spreader or the like is mounted on each of the upper surfaces 200f of the semiconductor chips 200, it can be attached to each of the semiconductor chips 200 accurately.

In addition, in the present embodiment, the heights of the upper surfaces of the first solder balls 21 and the second solder balls 22 can be adjusted without the need to change the sizes of the first solder balls 21 and the second solder balls 22. For this reason, the first solder balls 21 and the second solder balls 22 can be easily formed on the wiring board 10A.

In addition, in the present embodiment, if the first solder balls 21 and the second solder balls 22 are too large, a problem occurs in that adjacent solder balls 20 will bond together, resulting in unnecessary electrical continuity. In addition, if the first solder balls 21 and the second solder balls 22 are too small, a problem occurs in that they do not abut against the mounting pad portions on the opposing semiconductor chips 200 during mounting, for example. In the present embodiment, the occurrence of the above-mentioned problems can be reduced.

### Third Embodiment

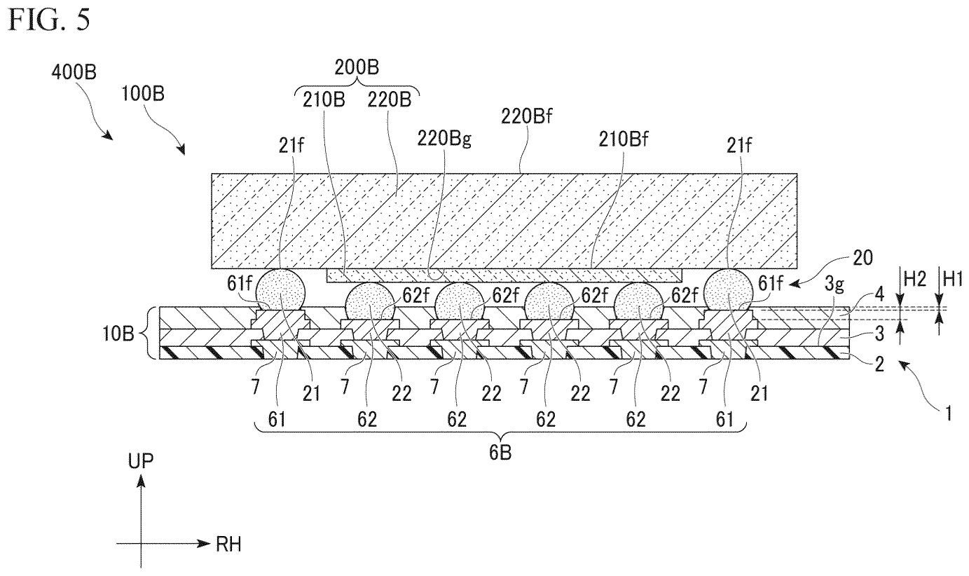

Next, a third embodiment of the present invention will be described with reference to FIG. 5. In any of the following embodiments, particularly the wiring board and the semiconductor chips are different from those of the second embodiment. A semiconductor device 400B according to the third embodiment of the present invention includes an FC-BGA wiring board 100B and semiconductor chips 200B. The semiconductor chips 200B include a first semiconductor chip 210B and a second semiconductor chip 220B that have different lengths in the left-right direction. The first semiconductor chip 210B is shorter in length in the left-right direction than the second semiconductor chip 220B. The FC-BGA wiring board 100B includes a wiring board 10B and solder balls 20. The semiconductor chips 200B may also include mounting pad portions (not shown), similarly to the second embodiment.

The wiring board 10B includes solder pads 6B on a part of a second layer 3 shown in FIG. 5. As shown in FIG. 5, in the wiring board 10B, the number of the solder pads 6B is different from that in the first embodiment. The solder pads 6B include, from the right side, one first solder pad 61, four second solder pads 62, and one first solder pad 61, which are aligned in a row in the left-right direction. The first solder pads 61 are provided on both ends of the wiring board 10B. The solder pads 6B are provided at approximately equal intervals. In the present embodiment, similar to the first embodiment and the second embodiment, the height H1 is set to an arbitrary height to be smaller than the height H2.

The solder balls 20 include first solder balls 21 and second solder balls 22, similar to the first embodiment and the second embodiment. The first solder balls 21 are formed on the upper surfaces 61f of the first solder pads 61. The second solder balls 22 are formed on the upper surfaces 62f of the second solder pads 62. The first solder balls 21 and the second solder balls 22 are formed to have approximately the same size and shape

Next, the semiconductor chips 200B are mounted on the FC-BGA wiring board 100B.

As shown in FIG. 5, first, the electrodes (the mounting pad portions) of the first semiconductor chip 210B are mounted to abut against the second solder balls 22 formed on the upper surfaces 62f of the second solder pads 62 of the wiring board 10B. At this time, in the upward-downward direction, the height of an upper surface 210Bf of the first semiconductor chip 210B and the heights of upper surfaces 21f of the first solder balls 21 are approximately the same.

Next, the second semiconductor chip 220B is mounted from above to overlap the first semiconductor chip 210B in the upward-downward direction. The electrodes (the mounting pad portions) of the second semiconductor chip 220B are mounted to abut against the first solder balls 21 formed on the upper surfaces 61f of the first solder pads 61 provided on both ends of the wiring board 10B.

With the above configuration, a plurality of semiconductor chips 200B are mounted on the FC-BGA wiring board 100B, and the semiconductor device 400B is formed.

Even in this case, in the FC-BGA wiring board 100B of the present embodiment, by adjusting the height H1 and height H2, the heights of the upper surfaces of the first solder balls 21 and the second solder balls 22 can be adjusted without the need to change the sizes of the first solder balls 21 and the second solder balls 22, which have approximately the same size and shape. For this reason, the second semiconductor chip 220B can be attached such that an upper surface 220Bf is approximately horizontal while being mounted such that a lower surface 220Bg is accurately abutted against the upper surface 210Bf of the first semiconductor chip 210B.

The present invention is not limited to the one embodiment described above. In addition, the constituent elements in one embodiment include those that a person skilled in the art can easily assume, those that are substantially the same, and those that are within the so-called equivalent range. Furthermore, the constituent elements disclosed in one embodiment can be combined as appropriate.

In the above, the embodiments of the present invention have been described in detail with reference to the drawings, but the specific configuration is not limited to the embodiments, and a design change and the like within a range not departing from the spirit of the present invention are also included. In addition, the constituent elements shown in the above-described embodiments and a modification example which will be shown below can be combined as appropriate.

### Modification Example

The wiring board of the FC-BGA wiring board of the present invention is not limited to the above-described embodiments, and may be constituted by multiple build-up layers. In addition, the third conductor portion and the solder pad provided on the wiring board of the FC-BGA wiring board of the present invention are not limited to the pad-on-via structure. In the third conductor portion and the solder pad, the pad may be provided at a position that does not overlap with the via in the upward-downward direction. In addition, the pad is not an essential component and may be a land. The wiring board of the present invention may be constituted by lands, wirings, or the like, or may be constituted by a combination of these.

In addition, the solder pad of the present invention does not have to be formed in a stacked manner like a stacked via, and may be formed, for example, in a stepped shape like a staggered via or in other shapes.

In addition, the FC-BGA wiring board of the present invention may further include an interposer substrate for connecting chips.

In addition, the number of solder pads, solder balls, or the like of the FC-BGA wiring board of the present invention is not limited. The solder pads, the solder balls, or the like can be set arbitrarily according to the size or shape of the wiring board and the mounting pad portions of the semiconductor chips.

In addition, the FC-BGA wiring board of the present invention does not necessarily have to include the solder balls 20. The solder balls 20 are not essential components. Furthermore, in the above-described embodiment, the first solder ball 21 and the second solder ball 22 are approximately the same in size and shape, but in the FC-BGA wiring board of the present invention, the first solder ball 21 and the second solder ball 22 may be different in size and shape.

In addition, in the above-described embodiment, the first solder pad 61, the second solder pad 62, and the third solder pad 63 are provided to be aligned in a row in the left-right direction, but the FC-BGA wiring board of the present invention is not limited to this, and the solder pads may be provided to be aligned in a row in a direction intersecting with the left-right direction. In addition, the number of rows is also not particularly limited.

In addition, in the above-described embodiment, the first conductor portion 81 and the second conductor portion 82 of the first solder pad 61, the second solder pad 62, and the third solder pad 63 are made of the same type of metal, but the present invention is not limited to this and may be made of different metals.

In addition, the semiconductor chips 200 mounted on the FC-BGA wiring board 100A according to the second embodiment of the present invention include the semiconductor chip 210 for optical communication and the semiconductor chip 220 for electrical communication, but the semiconductor chips are not particularly limited thereto. As the semiconductor chips 200, semiconductors well-known in the related art which are made of, for example, silicon, gallium arsenide, selenium, carbon, or the like may be mounted. In addition, similarly for the semiconductor chips 200B mounted on the FC-BGA wiring board 100B according to the third embodiment of the present invention, the semiconductor chips 200B are not particularly limited, and as the semiconductor chips 200B, semiconductors well-known in the related art which are made of, for example, silicon, gallium arsenide, selenium, carbon, or the like may be mounted. Furthermore, the present invention can also be applied to mounting forms such as a technique for stacking and mounting a semiconductor chip group (3D mounting) and a technique for mounting a semiconductor chip group on an interposer (2.5D mounting).

In addition, in the above-described embodiments, an example of mounting a semiconductor chip has been shown, but instead of the semiconductor chip, a semiconductor package in which a semiconductor is mounted on an intermediate substrate can also be mounted.

In addition, in the second embodiment described above, the solder pads 6A include, from the right side, two second solder pads 62, three first solder pads 61, and two second solder pads 62, which are aligned in a row in the left-right direction, but the present invention is not limited to this, and the solder pads may be provided to be aligned in a row in a direction intersecting with the left-right direction on the upper or lower surface of the FC-BGA wiring board. In addition, there are no limitations on the order or number of solder pads arranged, and the solder pads may be arranged from the left side instead of the right side. Furthermore, the number of rows is also not particularly limited. In addition, the solder pads 6B according to the third embodiment may be formed in a row in the left-right direction, similar to the solder pads 6A, or may be formed in a row in a direction intersecting with the left-right direction.

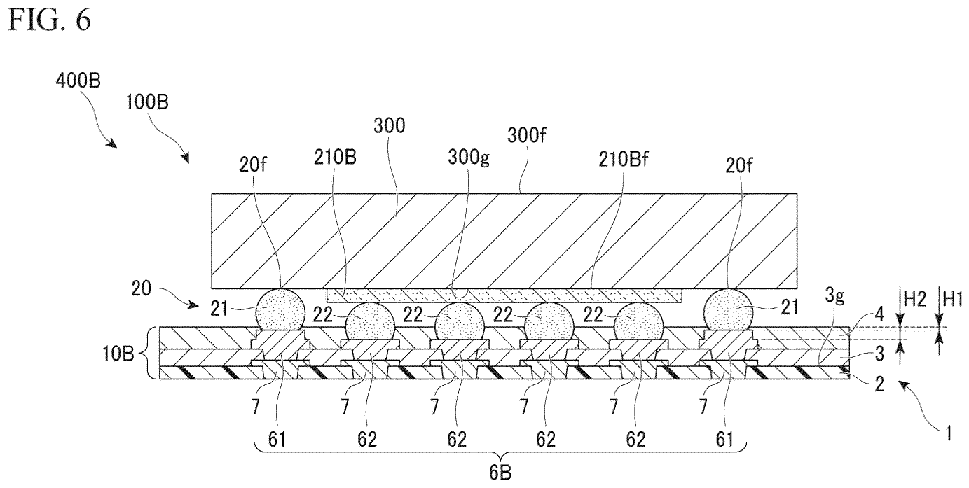

In addition, in the FC-BGA wiring board 100B according to the third embodiment of the present invention, as shown in FIG. 6, instead of the second semiconductor chip 220B of the semiconductor chips 200B, a heat spreader 300 may be mounted. Even in this case, in the FC-BGA wiring board 100B, by adjusting the height H1 and height H2, the heights of the upper surfaces of the solder balls 20 having approximately the same size and shape which are formed on the upper surfaces of the first solder pad 61, the second solder pad 62, and the third solder pad 63 can be adjusted arbitrarily. For this reason, the heat spreader 300 can be attached such that an upper surface 300f is approximately horizontal while being mounted such that a lower surface 300g is accurately abutted against the upper surface 210Bf of the first semiconductor chip 210B.

In any of the above embodiments, according to the wiring board, the semiconductor device, and the method for producing a wiring board of the present invention, it is possible to align the heights of the upper surfaces of different semiconductor packages even in a case in which the different semiconductor packages are mounted while maintaining the pitch interval between the solder balls uniform.

1. A wiring board with a multi-layer structure having a plurality of build-up layers,
wherein, among the build-up layers, a build-up layer on a front surface side formed last has a first solder pad and a second solder pad,
a solder resist layer is provided on the front surface side of the build-up layer on a front surface side, and
heights of the first solder pad and the second solder pad from front surfaces thereof to a front surface of the solder resist layer are different from each other.

2. The wiring board according to claim 1,
wherein the solder resist layer includes opening portions through which the front surface of the first solder pad and the front surface of the second solder pad are exposed to the front surface side, and
the front surface of the solder resist layer excluding the opening portions has an approximately uniform height.

3. The wiring board according to claim 1,
wherein the build-up layer on the front surface side further includes a third solder pad, and
the first solder pad, the second solder pad, and the third solder pad are formed at equal intervals.

4. The wiring board according to claim 1,
wherein the first solder pad and the second solder pad include solder balls having approximately a same diameter and approximately a same shape on the front surface side.

5. The wiring board according to claim 4,
wherein the first solder pad and the second solder pad are formed such that a difference between the heights is determined by heights of semiconductor chips to be bonded to the front surface side of the solder balls.

6. The wiring board according to claim 4,
wherein the first solder pad and the second solder pad are formed such that a difference between the heights is determined by heights of mounting pad portions of the semiconductor chips to be bonded to the front surface side of the solder balls.

7. A semiconductor device comprising:
the wiring board according to claim 5; and
the semiconductor chips.

8. A semiconductor device comprising:
the wiring board according to claim 6;
the semiconductor chips; and
the mounting pad portions.

9. A method for producing a wiring board,
wherein, among a plurality of build-up layers, a build-up layer on a front surface side formed last has a first solder pad and a second solder pad,
a solder resist layer is provided on the front surface side of the build-up layer on a front surface side, and
heights of the first solder pad and the second solder pad from front surfaces thereof to a front surface of the solder resist layer are different from each other,
the method comprising at least:
a step of forming a wiring layer, the first solder pad, and the second solder pad in the build-up layer on the front surface side;
a step of forming a plating resist layer such that a part of the front surface of the first solder pad and a part of the front surface of the second solder pad are exposed to the front surface side;
a step of depositing copper on the front surface side of the first solder pad and the second solder pad by a copper plating treatment;
a step of stripping the plating resist layer;
a step of forming the solder resist layer on the front surface side of the build-up layer on the front surface side; and
a step of providing, in the solder resist layer, opening portions through which a part of the front surface of the first solder pad and a part of the front surface of the second solder pad are exposed to the front surface side.
